(19) United States
(12) Patent Application Publication
(10) Pub. No.: US 2014/0138129 A1
(43) Pub. Date: May 22, 2014

(54) SUBSTRATE HAVING A LOW COEFFICIENT OF THERMAL EXPANSION (CTE) COPPER COMPOSITE MATERIAL

(71) Applicant: QUALCOMM INCORPORATED, San Diego, CA (US)

(72) Inventors: Layal L. Rouhana, San Diego, CA (US); Jomaa Houssam W., San Diego, CA (US); Omar J. Bchir, San Diego, CA (US)

(73) Assignee: Qualcomm Incorporated, San Diego, CA (US)

(21) Appl. No.: 13/715,235

(22) Filed: Dec. 14, 2012

Related U.S. Application Data
(60) Provisional application No. 61/727,212, filed on Nov. 16, 2012.

(51) Int. Cl. H05K 3/10; H05K 1/09

(52) U.S. Cl. CPC H05K 3/10; H05K 1/092; B82Y 99/00
USPC 174/257; 427/97.3; 216/13; 205/118; 205/136; 977/742; 977/932

(57) ABSTRACT

Some implementations provide a substrate that includes a first dielectric layer, a second dielectric layer, a core layer, and a composite conductive trace. The first and second dielectric layers have a first coefficient of thermal expansion (CTE). The core layer is between the first dielectric layer and the second dielectric layer. The composite conductive trace is between the first dielectric layer and the second dielectric layer. The composite conductive trace includes copper and another material. The composite conductive trace has a second CTE that is less than a third CTE for copper to more closely match the first CTE for the first and second dielectric layers.

### CLAIM OF PRIORITY UNDER 35 U.S.C. §119

The present application claims priority to U.S. Provisional Application No. 61/727,212 entitled “Substrate Having a Low Coefficient of Thermal Expansion (CTE) Copper Composite Material”, filed Nov. 16, 2012, which is hereby expressly incorporated by reference herein.

### BACKGROUND

1. Field

Various features relate to a substrate having a low coefficient of thermal expansion (CTE) copper composite material.

2. Background

There is an ongoing demand to shrink the size of semiconductor device packages. One way to achieve this is to reduce the thickness of the substrate of an integrated circuit, or other integrated circuit components in a device. A substrate is typically made of a central core layer and multiple dielectric layers on either side of the central core layer. Copper or other conductive material is used on the surface of the core and dielectric layers to route signals from the active component of the integrated circuit to the motherboard and other components in a device. The core layer includes a cured dielectric layer with metal (e.g., copper) foil bonded on both sides of the cured dielectric layer (e.g., glass, resin). The buildup dielectric layer is often referred to as a prepreg (pre-impregnated) layer or buildup epoxy and may be laminated or pressed on top of the core during manufacturing. The manufacturing process may or may not use copper foil during the lamination process. In addition, the substrate may also include vias that are made of copper.

Thinning the substrate of an integrated circuit reduces the stiffness of the composite structure and leads to warpage during chip and/or board mount as well as increasing the overall coplanarity of the package, which can lead to surface mount yield issues. These high temperature warpage and coplanarity problems are related to material properties including the coefficient of thermal expansion (CTE) of the materials comprising the substrate. To eliminate, reduce or minimize these warpage and coplanarity problems, the effective CTE of the substrate needs to be reduced. One approach to reduce the CTE of the substrate is to use very low CTE materials for the dielectric layers (e.g., prepreg or epoxy buildup and core layers). Current available materials in the market for organic substrates can reach down as low as 1-3 parts-per-million per degree Celsius (ppm/° C.). However, the use of these ultra-low CTE materials may be insufficient to offset the high CTE of copper (17 ppm/° C.), especially as the overall substrate thickness is reduced.

In order to enable the growing need of thinning packages for mobile and other devices, additional reduction in the conductor material CTE is needed to enable substrates that meet warpage and coplanarity requirements during chip mount and surface mount.

### SUMMARY

Various features, apparatus and methods described herein provide a substrate for an integrated circuit (IC).

A first example provides a substrate that includes a first dielectric layer, a second dielectric layer, a core layer, and a composite conductive material. The first and second dielectric layers have a first coefficient of thermal expansion (CTE). The core layer is between the first dielectric layer and the second dielectric layer. The composite conductive trace may be on the first dielectric layer, between the first dielectric layer and the core layer. The composite trace may be between the core layer and the second dielectric layer. The composite trace may be on the second dielectric layer. The composite conductive trace includes copper and another material. The composite conductive trace has a second CTE that is less than a third CTE for copper to more closely match the first CTE for the first and second dielectric layers.

According to one aspect, the another material is carbon nanotubes (CNTs). In some implementations, the CNTs may include nanotubes coated with a mixed shell of zwitterrionic and a positively charged conductive polymer. In some implementations, the CNTs may include nanotubes coated with a mixed shell of zwitterrionic and a non-conductive polymer.

According to another aspect, the another material has a fourth CTE value that is negative. The another material may be a nickel/tin alloy in some implementations. The substrate may be for an integrated circuit (IC). The substrate may be for a printed circuit board (PCB) in some implementations. In some implementations, the composite conductive trace is located between the core layer and the first dielectric layer.

A second example provides a method for manufacturing a substrate. The method provides a core layer for the substrate. The method also provides a composite conductive trace. The composite conductive trace includes copper and another material. The composite conductive trace has a first coefficient of thermal expansion (CTE) that is less than a second CTE for copper to more closely match a third CTE for a first and second dielectric layers, and the core. The method provides the first and second dielectric layers, such that the core layer is between the first and second dielectric layers.

According to one aspect, providing the composite conductive trace includes paste printing a copper composite layer on at least one of the core layer, first dielectric layer and/or second dielectric layer. In some implementations, the copper composite layer is a copper composite foil. In some implementations, providing the composite conductive trace includes electrolytically plating a copper composite layer on at least the core layer. In some implementations, providing the composite conductive trace includes electrolytically plating a copper composite layer on at least the first dielectric layer.

According to another aspect, providing the composite conductive trace includes drilling the core layer to provide a trace pattern on the core layer and filling the trace pattern with a copper composite paste to provide the composite conductive trace. In some implementations, providing the composite conductive trace further includes etching a copper foil layer on the core layer before drilling the core layer.

According to yet another aspect, providing the composite conductive trace includes filling a trace pattern with a copper composite paste. The trace pattern is in at least one of the core layer, first dielectric layer and/or second dielectric layer.

According to an aspect, providing the composite conductive trace includes applying a dry film resist (DFR) on a first copper layer of the core layer, patterning the DFR, electrolytically plate a second copper composite layer through the DFR, removing the DFR, and selectively etching the first copper layer of the particular dielectric layer to provide the composite conductive trace. In some implementations, providing the composite conductive trace further includes drilling at least one via pattern in the core layer before applying the DFR on the first copper layer of the core layer. In some implementations, the first copper layer is a copper foil having at thickness of 5 microns (μm) or less. In some implementations, providing the composite conductive trace further includes thinning the first copper layer before applying the DFR on the first copper layer of the core layer. The first copper layer is a copper foil having a thickness of 12 microns (μm) or less before the thinning.

According to another aspect, providing the composite conductive trace includes providing a first copper layer and a primer layer on the core layer. The primer layer is located between the first copper layer and the core layer. In some implementations, providing the composite conductive trace also includes etching the first copper layer, the etching leaving the primer layer on the core layer, electroless plating a second copper layer on top of the layer of primer, applying a dry film resist (DFR) on top of the second copper composite layer, patterning the DFR, electrolytically plate a third copper composite layer through the DFR, removing the DFR, and selectively etching the second copper composite layer of the core layer to provide the composite conductive trace.

### DRAWINGS

Various features, nature and advantages may become apparent from the detailed description set forth below when taken in conjunction with the drawings in which like reference characters identify correspondingly throughout.

FIG. 1 illustrates a substrate that includes low coefficient of thermal expansion copper composite materials.

FIG. 2 illustrates a flow diagram for manufacturing a substrate with low coefficient of thermal expansion copper composite materials.

FIGS. 3A-3D illustrate a shortened sequence of a paste process for manufacturing a substrate with low coefficient of thermal expansion copper composite materials.

FIGS. 4A-4D illustrate a shortened sequence of a plating process for manufacturing a substrate with low coefficient of thermal expansion copper composite materials.

FIG. 5 illustrates a flow diagram of a modified semi-additive processing (mSAP) patterning process for manufacturing a substrate with low coefficient of thermal expansion copper composite materials.

FIG. 6 illustrates a sequence of a mSAP patterning process on a layer of a substrate.

FIG. 7 illustrates a flow diagram of a semi-additive processing (SAP) patterning process for manufacturing a substrate with low coefficient of thermal expansion copper composite materials.

FIG. 8 illustrates a sequence of a SAP patterning process on a layer of a substrate.

FIG. 9 illustrates a flow diagram of a conceptual plating process.

FIG. 10 illustrates a flow diagram of a conceptual paste process.

FIG. 11 illustrates various electronic devices that may integrate an integrated circuit and/or PCB described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

### Overview

Some novel features pertain to a substrate for an integrated circuit that includes a first dielectric layer, a second dielectric layer, a core layer between the first dielectric layer and the second dielectric layer, and a composite conductive trace between the first dielectric layer and the second dielectric layer. The first and second dielectric layers have a first coefficient of thermal expansion (CTE). The composite conductive trace includes copper and another material. The composite conductive trace has a second CTE that is less than a third CTE for copper to more closely match the first CTE for the first and second dielectric layers.

In some implementations, the substrate that includes the composite conductive trace with the second CTE may be manufactured by using a paste printing process or a plating process (e.g., semi-additive patterning (SAP) process, modified semi-additive patterning (mSAP) process).

### Exemplary Substrate Having Low CTE Copper Composite Materials

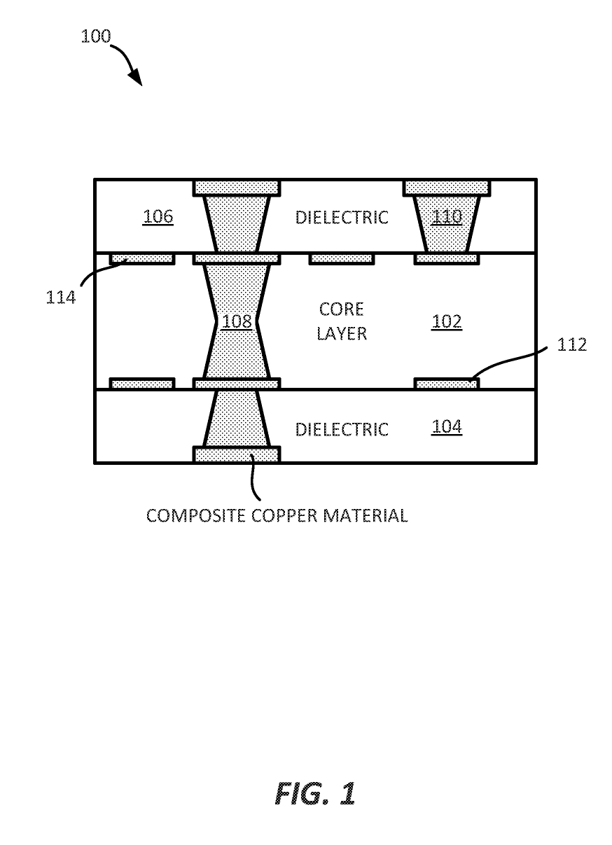

FIG. 1 illustrates an example of a substrate of an integrated circuit that utilizes one or more metal layers and/or metal components with a low coefficient of thermal expansion (CTE) in some implementations. Specifically, FIG. 1 illustrates a substrate 100 that includes a core layer 102, a first dielectric layer 104, a second dielectric layer 106, a first via 108, a second via 110, a first trace 112 and a second trace 114. The substrate 100 may also include other metal components (e.g., via pads).

The core layer 102 is positioned between the first dielectric layer 104 and the second dielectric layer 106. More specifically, the first dielectric layer 104 is positioned above the core layer 102, and the second dielectric layer 106 is positioned below the core layer 102. The core layer 102 may be a dielectric layer. In some implementations, the core layer 102, the first and second dielectric layers 104-106 may be made of fiberglass, epoxy, and/or other types of filled resins.

Different implementations may have different thicknesses for the core layer 102, the dielectric layers 104-106 and the various metal components (e.g., via 108). In some implementations, the core layer 102 may have a thickness between 40-800 microns (μm), the dielectric layer may have a thickness between 25-80 microns (μm), and some of the various metal components (e.g., trace 112) may have a thickness of 5-70 microns (μm).

As further shown in FIG. 1 the first via 108 traverses across the first dielectric layer 104, the core layer 102 and the second dielectric layer 106. The first via 108 may include several vias and via pads. The second via 110 is located in the second dielectric layer 106. The first and second conductive traces 112-114 are located in the core layer 102. More specifically, the first trace 112 is located in a bottom portion of the core layer 102, while the second trace 114 is located in the top portion of the core layer 102. In addition, one or more traces may also be located in one or more of the dielectric layers (e.g., first dielectric layer 104, second dielectric layer 106) in some implementations. The dielectric layers 104-106 may each be a buildup dielectric layer that may be referred to as a prepreg (pre-impregnated) layer and may be laminated or pressed on top of the core layer (e.g., core layer 102) during manufacturing. In some implementations, the prepreg layer may be laminated or pressed on top of another prepreg layer.

In some implementations, some or all of the metal layers and/or metal components (e.g., vias, via pads, conductive traces) of the substrate 100 are made of a copper composite material that has a low coefficient of thermal expansion (CTE) value. These metal layers and/or metal components are made of a material with low CTE value in order to more closely match the CTE value of the substrate (e.g., the CTE of the core layer and/or one or more dielectric layers). In some implementations, lowering the CTE of the metal layers and/or metal components minimizes or reduces warpage and coplanarity problems that may arise when using thin substrates. The CTE of a substrate (e.g., core layer, dielectric layer) may be 4 ppm/° C. in some embodiments. Thus, some implementations may use a copper composite material that has a low CTE (e.g., CTE that is less than 10 ppm/° C.) that is as close as possible to the CTE of the dielectric layers. Different copper composite materials with low CTE will now be described below.

### Exemplary Copper Composite Materials

As mentioned above, different implementations may use different copper composite materials. For example, a copper composite material may be (1) a combination of copper and carbon nanotubes (CNTs) (CNT has a low CTE and high electrical and thermal conductivities), (2) a combination of copper and a material with a negative CTE, such as nickel/tin (Ni/Ti) alloy, or (3) a combination of copper and any ultra-low CTE material (e.g., molybdenum (mo), tin and nickel). In some implementations, an ultra-low CTE material may be defined as any material with a CTE between 1-3 ppm/° C. In some implementations, copper may be combined with CNT, which may be coated with a mixed shell of zwitterionic and positively charged conductive polymers. Another example of a copper composite material includes a combination of pure copper plated on top of a copper nickel/tin alloy.

In some implementations, the CNT may be mixed with the copper plating solution to form a working bath that includes CNT and CuSO₄. In some implementations, the working bath that includes the CNT (and possibly mixed shell of zwitterionic and positively charged polymers) and CuSO₄ may be used in a plating process. In some implementations, CuSO₄ is the source of copper ions while charged CNT will co-deposit with the copper when a current is applied across the panel surface. Zwitter ions may be used to stabilize the CNT from aggregation in the bath. In some implementations, a mixed shell of zwitterion and positively charged electrically conductive polymers will coat the CNTs to stabilize and charge the composite to co-deposit with copper.

Another factor that may need to be considered when choosing a copper composite material is the electrical conductivity of the copper composite material. Although it may be desirable to lower the CTE of the material to more closely match the CTE of the dielectric layers, the ability of the copper composite material to properly and reliably conduct electrical signals may be just as important. This may be important since many of today's devices operate at very low voltages. Thus, when selecting a copper composite material, consideration must be given as to whether the metal components will be able to properly and reliably conduct electrical signals. In the case of power signals wires (which are comparatively larger than other components in the substrate) this may not be an issue. However, for smaller metal components, such as traces and/or vias, this may be an issue.

The above copper composite materials are merely examples of possible materials, and should not be construed to limit copper composite materials to these examples. Other copper composite materials may also be used as well. The use of these materials will be further described below with respect to the various processes and/or methods for manufacturing a substrate that has a low CTE copper composite material.

Having provided several possible copper composite materials, a high level flow diagram of a method for providing/manufacturing a substrate having low CTE metal layers and/or components will now be described below.

Exemplary High Level Method for Manufacturing a Substrate with Low CTE Copper Composite Materials

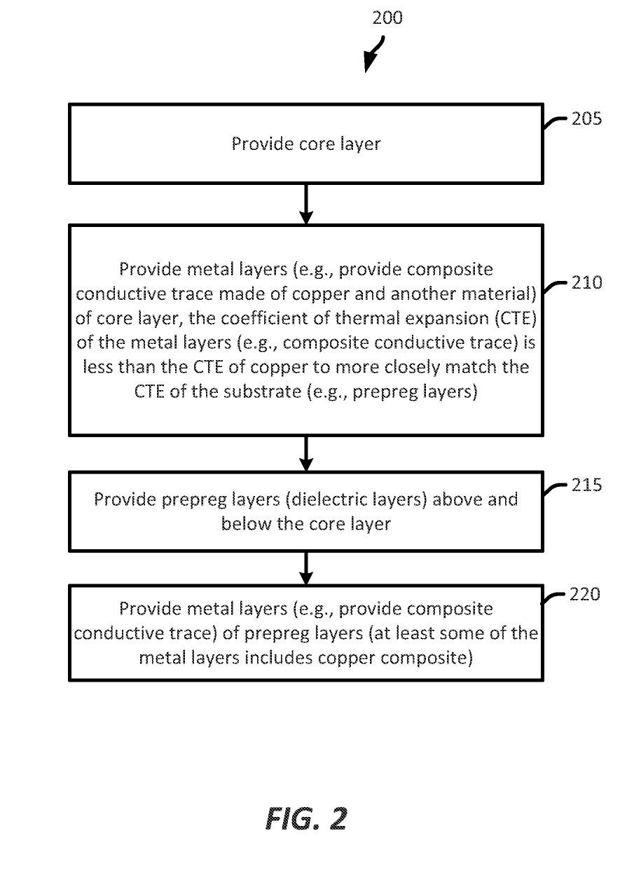

FIG. 2 illustrates a high level flow diagram for providing/manufacturing a substrate with a low coefficient of thermal expansion (CTE) copper composite material in some implementations. As shown in FIG. 2, the method begins by providing (at 205) a core layer. The core layer may be a core layer for an integrated circuit (IC). In some implementations, providing the core layer may include coating and/or impregnating a dielectric material with resin/fiberglass/epoxy and then curing the dielectric material, with copper foil above and below the dielectric layer. In some implementations, providing (at 205) the core layer may include cleaning the core layer to allow subsequent layers to be adhered to the core layer.

Next, the method provides (at 210) the metal layers of the core layer. In some implementations, this may include depositing one or more metal layers (e.g., copper composite material) on the core layer. For example, a metal layer may be deposited on the top of the core layer and/or the bottom of the core layer. In some implementations, providing (at 210) the metal layers may also include providing the features and/or components (e.g., trace, vias) for the core layer of the substrate. For example, providing the metal layers may include providing a composite conductive trace that includes copper and another material, where the composite conductive trace has a first coefficient of thermal expansion (CTE) that is less than a second CTE for copper to more closely match a third CTE for a first and second dielectric layers (e.g., core layer). Different implementations may provide these features differently. For example, some implementations may use a plating process, while other implementations may use a printing type process. These different processes will be further described below in the next section.

After providing (at 210) the metal layers for the core layer, the method provides (at 215) one or more prepreg layers for the substrate. This may include laminating one or more dielectric layers on the core layer. In some implementations, the method provides (at 215) a first dielectric layer above the core layer and a second dielectric layer below the core layer. The first and second dielectric layers may be made of resin, fiberglass, and/or filled epoxy materials in some implementations. In another embodiment, a dielectric layer may include filled or unfilled epoxy which does not include any fiber glass.

Next, the method provides (at 220) the metal layers of the prepreg (dielectric) layers. In some implementations, this may include depositing one or more metal layers (e.g., copper composite material) on the dielectric layers. For example, a metal layer may be deposited on the top of a first dielectric layer and/or the bottom of a second dielectric layer. In some implementations, providing (at 220) the metal layers may also include providing the features and/or components (e.g., trace, vias) for prepreg layers of the substrate. As described above, different implementations may use different processes for providing the metal layers and/or the features.

Once the substrate is provided/manufactured, the method may mask the conductive components (e.g., trace) with a solder mask or similar dielectric materials. The method may then perform a bumping process to form the interconnect structure between a die that includes the substrate and a printed circuit board (PCB). The bumping process may include ball grid array, or an under bump metallization (UBM) structure (e.g., copper pillar) with solder to couple to the PCB in some implementations.

Having described a high level method for providing/manufacturing a substrate that includes a low CTE copper composite material, several detailed examples of sequences and processes for providing/manufacturing such a substrate will now be described below.

### Exemplary Processes for Manufacturing Substrate

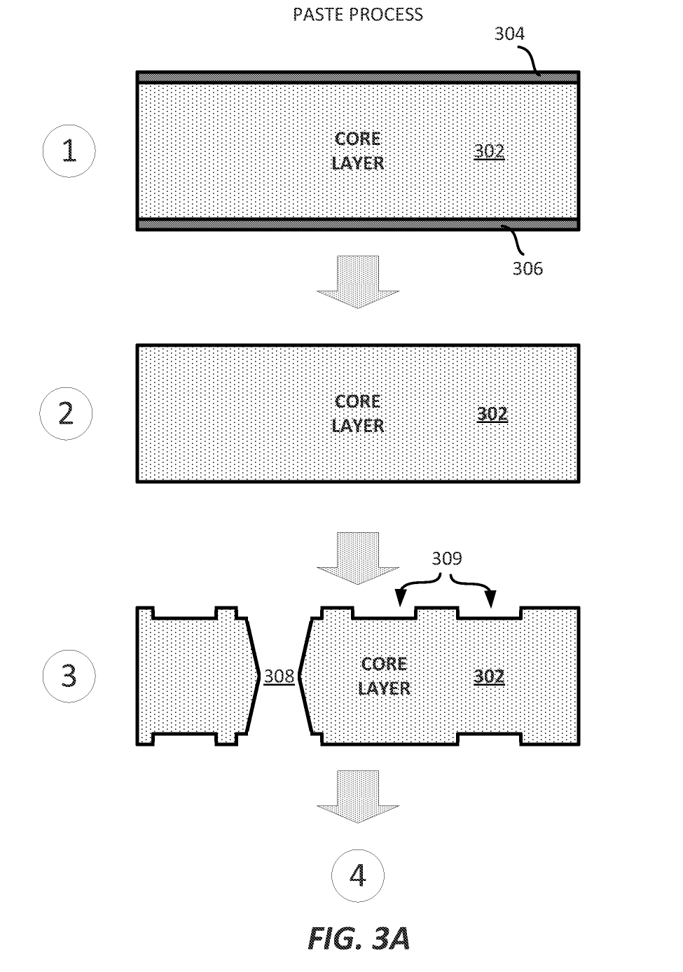

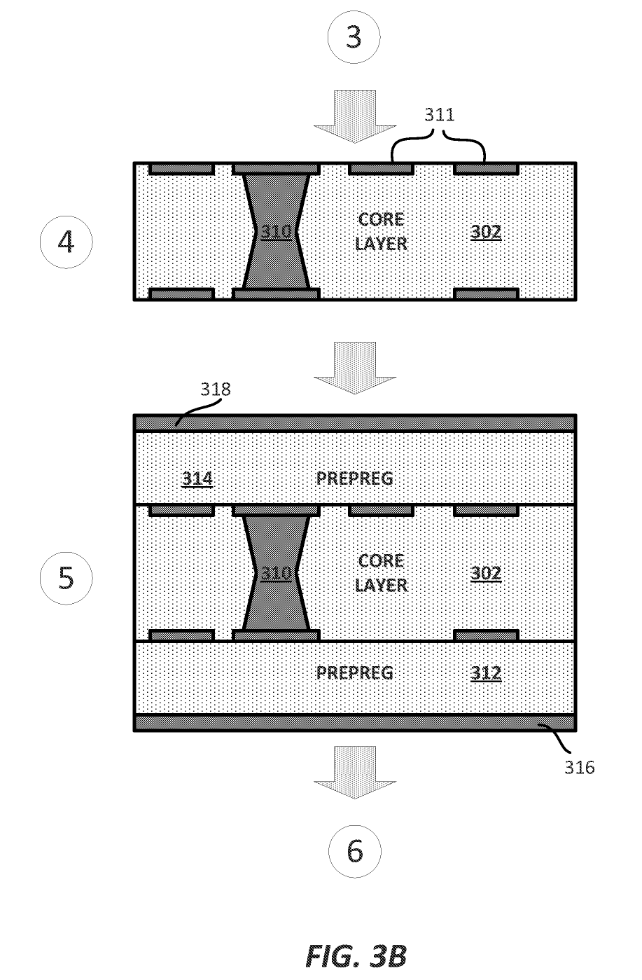

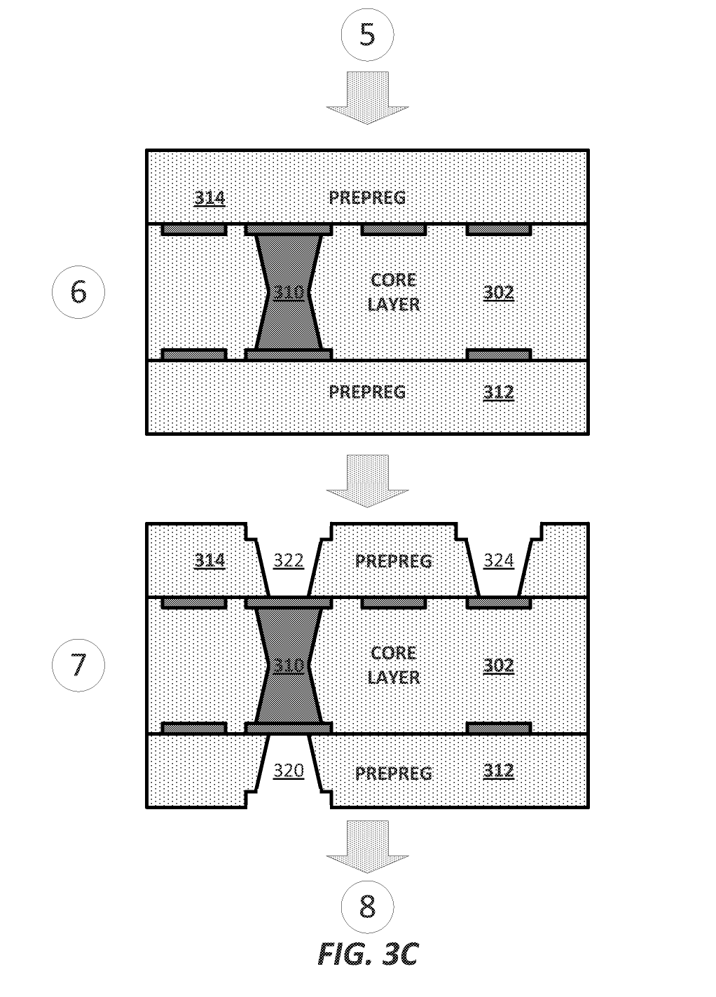

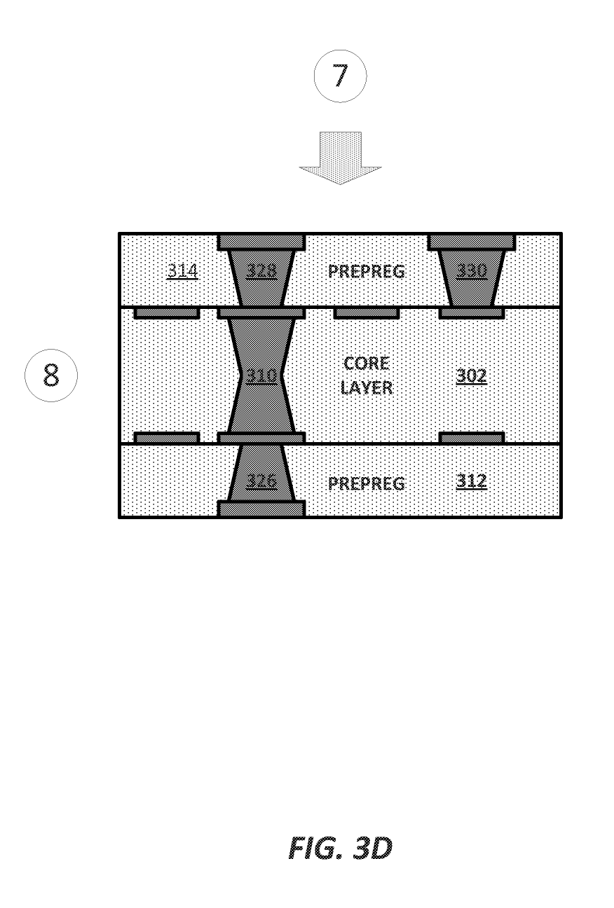

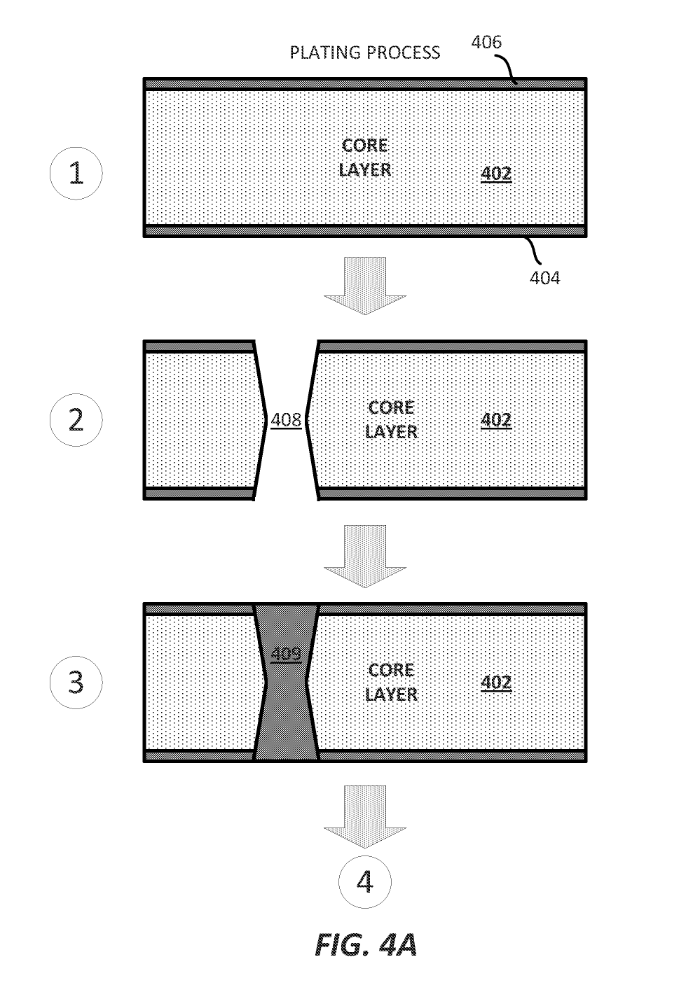

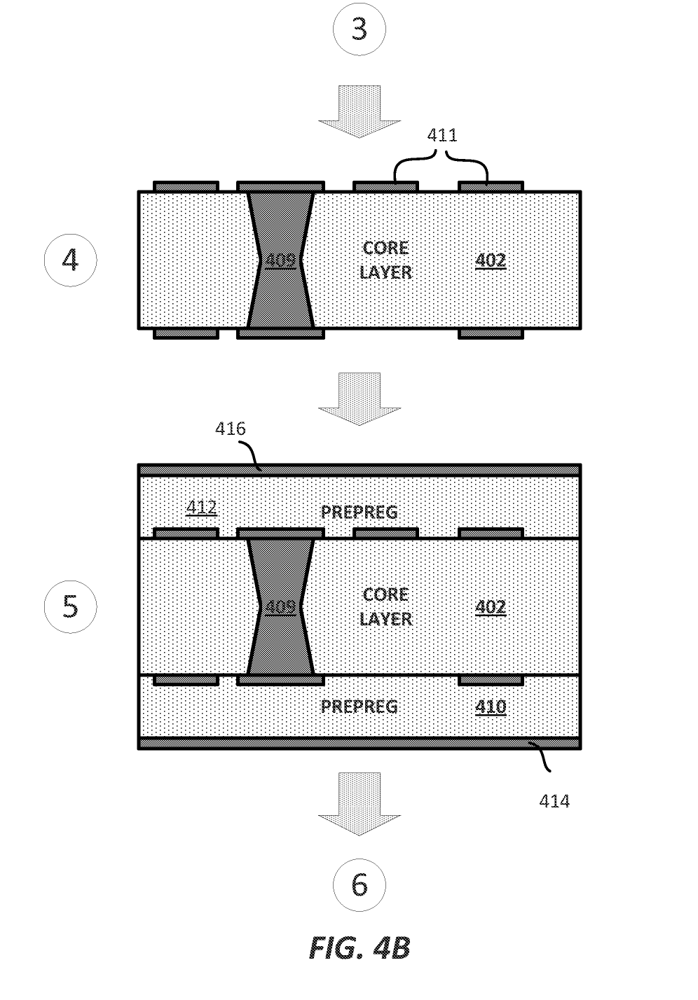

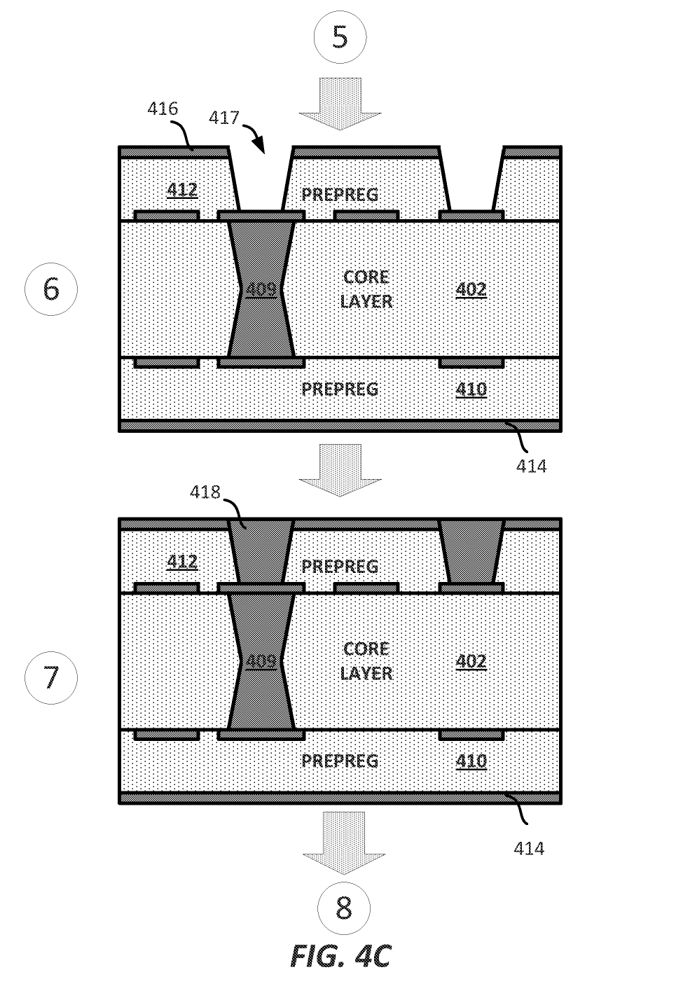

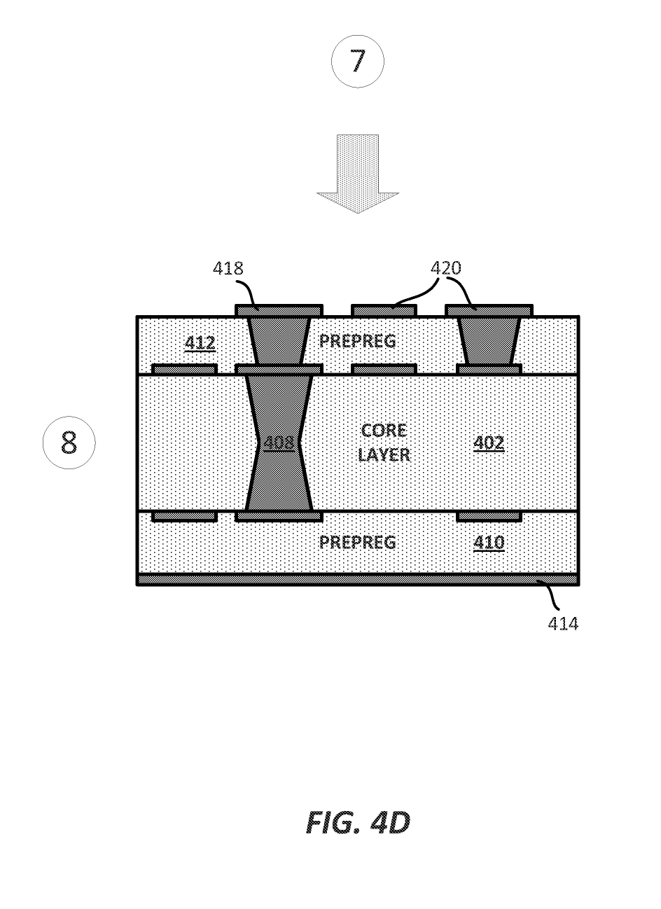

As mentioned above in FIG. 2, some implementations may manufacture a substrate that includes a low coefficient of thermal expansion (CTE) copper composite material by using a printing type process or a plating process. These two processes will now be described below with reference to FIGS. 3A-3D and 4A-4D.

Specifically, FIGS. 3A-3D illustrate a shortened sequence of a paste process (which is a printing type process) for providing/manufacturing a substrate, while FIGS. 4A-4D illustrate a shortened sequence of a plating process for providing/manufacturing a substrate. It should be noted that for the purpose of clarity and simplification, the processes of FIGS. 3A-3D and FIGS. 4A-4D do not necessarily include all the steps and/or stages of manufacturing a substrate with a low CTE copper composite material. Moreover, in some instances, several steps and/or stages may have been combined into a single step and/or stage in order to simplify the description of the processes. It should also be noted that the shapes of the patterns, pattern features, components (e.g., composite conductive trace, vias) in FIGS. 3A-3D are merely conceptual illustrations and are not intended to necessarily represent the actual shape and form of the patterns, pattern features and components.

As shown in FIG. 3A, the paste process begins (at stage 1) with a core layer 302. The core layer 302 is a dielectric in some implementations. Often a material manufacturer or material supplier, supplies the core layer 302 with a first metal layer 304 and a second metal layer 306 to a substrate manufacturer. In some implementations, one or both of the metal layers 304-306 is a copper material (e.g., copper foil). Next the process etches (at stage 2) the metal layers 304-306 from the core layer 302 (e.g., completely removes the metal layer 304-306 from the core layer 302). However, in some implementations, the process of etching the metal layers 304-306 may be omitted/skipped when the core layer 302 is supplied without such metal layers 304-306. In such instances, the paste process may begin with just the core layer 302.

The process then provides (at stage 3) pattern features (e.g., trace pattern features) in the core layer 302 (e.g., in the dielectric of the core layer 302). In some implementations, the providing/defining of the pattern features may be performed by using a laser to drill one or more pattern features into the dielectric of the core layer 302. As shown in stage 3, the drilling process (e.g., laser drilling) has defined a via pattern feature 308 in the core layer 302 and trace pattern features 309 in the dielectric of the core layer 302. The via pattern feature 308 and the trace pattern features 309 are empty since there is no material there. Different types of lasers may be used to drill the via pattern feature 308 and the trace pattern feature 309 respectively depending on the manufacturing process.

Next, the process fills (at stage 4) the pattern features (e.g., via pattern 308) with a conductive paste (e.g., copper composite paste). Once the pattern features have been filled with the conductive paste, they become the features and/or components of the substrate. In this example, once the via pattern feature 308 is filled with a conductive paste (e.g., copper composite paste), the via pattern feature 308 becomes a via feature 310. Similarly, once the trace pattern features 309 is filled with a conductive paste, the trace pattern features 309 become the composite trace features 311 (e.g., composite conductive trace). The filling of the pattern features in stage 4 is illustrated by the shading of the features/components (e.g., composite conductive trace) in the core layer 302 of the substrate. In some implementations, the paste is then sintered or cured depending on the composition of the paste.

Next, the paste process provides (at stage 5) one or more prepreg layers (dielectric layers) on the core layer 302. As shown in stage 5, a first dielectric layer 312 is coupled to the bottom of the core layer 302, while a second dielectric layer 314 is coupled to the top of the core layer 302. As in the case of the core layer, often a substrate manufacturer or substrate supplier, may supply the prepreg layers 312-314 with metal layers, if hot pressing is done. Alternatively, in another embodiment, substrate manufacturers may vacuum laminate an epoxy material which may or may not be filled on the patterned core. In some implementations, this laminated epoxy will not have copper on top. As shown in stage 5, a third metal layer 316 (e.g., copper foil) is coupled to the first dielectric layer 312 and a fourth metal layer 318 (e.g., copper foil) is coupled to the second dielectric layer 314. In some implementations, one or both of the metal layers 316-318 is a copper material (e.g., copper foil).

Next the process etches (at stage 6) the metal layers 316-318 from the prepreg layers 312-314 (e.g., completely removes the metal layer 316-318 from the prepreg layer 312-314). However, in some implementations, the process of etching the metal layers 316-318 may be omitted/skipped when either or both the prepreg layers 312-314 are supplied without such metal layers 316-318.

The process then provides (at stage 7) pattern features (e.g., trace pattern features) in the prepreg layers 312-314 (e.g., in the dielectric of the prepreg layer 312-314). In some implementations, the providing/defining of the pattern features may be performed by using a laser to drill one or more pattern features into the dielectric of the core layers 312-314. As shown in stage 7, the drilling process (e.g., laser drilling) has defined several via pattern features (e.g., via pattern features 320, 322, 324) in the prepreg layers 312-314. Although not shown, other pattern features (e.g., trace pattern features) may also be defined in the prepreg layers 312-314. The via pattern features 322-324 are empty since there is no material there. The pattern features may be defined concurrently or sequentially. In some implementations, pattern features may first be defined in the first prepreg layer 312 and then in the second prepreg layer 314, or vice versa.

Next, the process fills (at stage 8) the pattern features (e.g., via pattern features 320-324) with a conductive paste (e.g., copper composite paste). Once the pattern features have been filled with the conductive paste, they become the features and/or components of the substrate. In this example, once the via pattern features 320-324 is filled with a conductive paste (e.g., copper composite paste), the via pattern features 322-324 become via features 326-330. The filling of the pattern features in stage 8 is illustrated by the shading of the features/components (e.g., composite conductive trace) in the prepreg layers 312-314 of the substrate.

In some implementations, additional layers may be added to the substrate. As such, the paste process may be repeated several times (e.g., stages 5-8 may be repeated) until a desired number of layers is reached. Having described a paste process for providing/manufacturing a substrate with a low CTE copper composite material, a plating process will now be described below.

As mentioned above, FIGS. 4A-4D illustrate a shortened sequence of a plating process for providing/manufacturing a substrate with a low CTE copper composite material in some implementations. Different implementations may use different plating processes. Examples of plating processes include a semi-additive patterning (SAP) plating process and a modified semi-additive patterning (mSAP) plating process. These different plating processes will be further described below in the next section, after providing an overview of a plating process.

In some implementations, the copper composite material that is used in the plating processes described below may include a combination of copper and CNTs and/or it may include a combination of copper and nickel/tin alloy. In some implementations, when the combination of copper and CNTs is used, the CNTs may be coated with mixed shell of zwitterionic and positively charged conductive polymers in order to stabilize the CNTs.

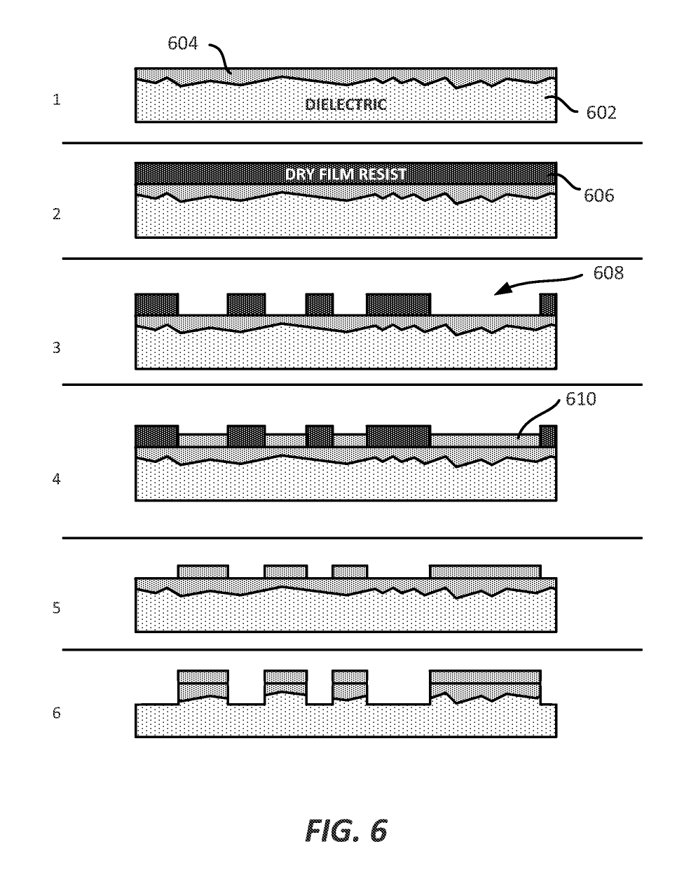

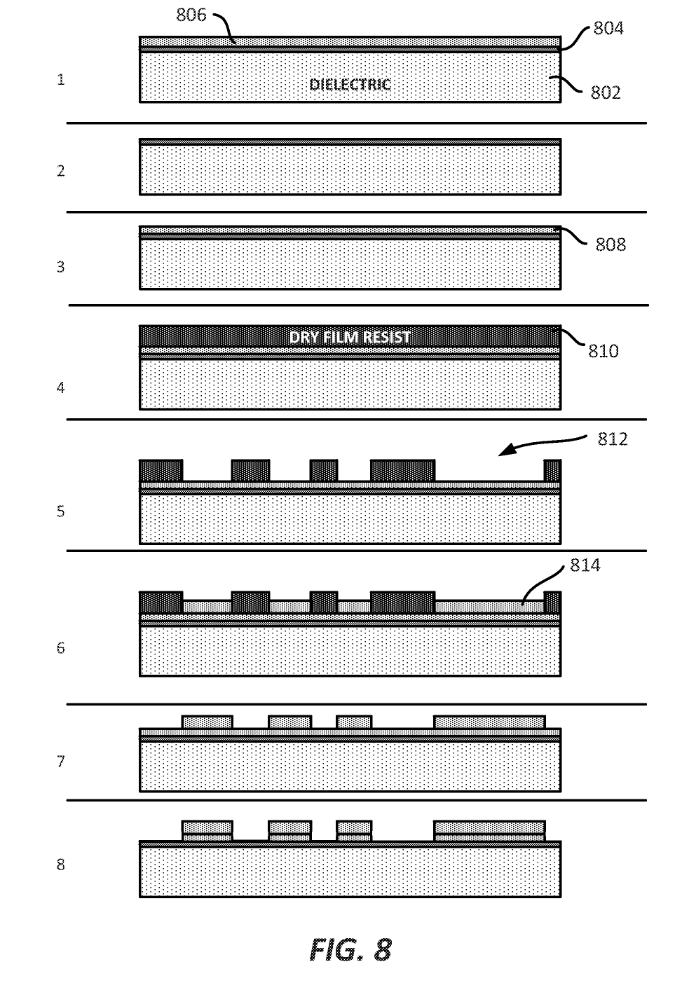

FIGS. 4A-4D illustrates a generalized high level plating process of some implementations. As such, the plating process of FIGS. 4A-4D does not necessarily include all the steps and/or stages of providing/manufacturing a substrate with a low CTE copper composite material. Moreover, in some instances, several steps and/or stages may have been combined into a single step and/or stage in order to simplify the description of the processes. More specific and detailed plating processes are described in FIGS. 6 and 8. It should also be noted that the shapes of the patterns, pattern features, components (e.g., composite conductive trace, vias) in FIGS. 4A-4D are merely conceptual illustrations and are not intended to necessarily represent the actual shape and form of the patterns, pattern features and components.

As shown in FIG. 4A, the plating process begins (at stage 1) with a core layer 402. The core layer 402 is a dielectric in some implementations. Often a material manufacturer or a material supplier may, may supply the core layer 402 with a first metal layer 404 and a second metal layer 406 to a substrate manufacturer. Different implementations may use different metal layers 404-406. In some implementations, one or both of the metal layers 404-406 is a copper material (e.g., copper composite foil). In some implementations, one or more of the metal layers (e.g., copper composite foil) may have a thickness of 2-5 microns (μm). In some implementations, one or more metal layers 404-406 may be a low CTE copper composite foil that has a thickness of 3-12 microns (μm). In such instances, the process may optionally etch down the thickness of the low CTE copper composite foil. In some implementations, one or more of the metal layers 404-406 may be a copper layer with a primer.

Next, the process performs (at stage 2) a drilling operation on the core layer 402, which defines one or more pattern features (e.g., via pattern feature 408) on the substrate. The drilling operation may be a laser drilling operation. The drilling operation may traverse through the first metal layer 404, dielectric of the core layer 402, and the second metal layer 406.

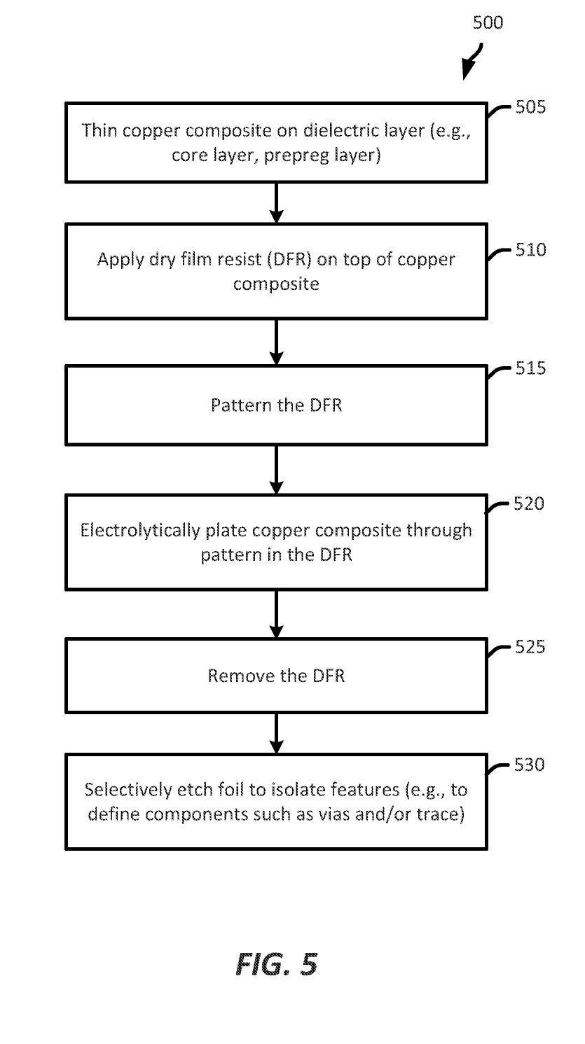

The process then performs (at stage 3) one or more plating processes, which defines the features (e.g., via feature 409) of the substrate. In some implementations, the via feature 409 may provide an interconnection between the front and the back of the substrate. Different implementations may perform the plating process differently. In some implementations, an electroless copper seed is deposited on (e.g., the surface of) the pattern features (e.g., via pattern feature 408), which forms the via feature 409. Stage 3 of FIG. 4A illustrates that only the surface of the pattern feature 408 is covered, which means a layer of the electroless copper seed is formed on the wall of the feature 409. Some implementations may perform fill plating to define the features/components of the substrate. In some implementations, the fill plating may be formed on one or more of the metal layers 404-406. That is, at stage 3, some implementations, may add an additional layer (e.g., copper, copper composite) on the metal layers 404-406. In some implementations, the core layer 402 may be received without any metal layers 404-406 from material suppliers. In such instances, at stage 3, the process may add/deposit/plate one or more metal layers on the core layer 402. The various processes/methods for adding, depositing, or plating copper and/or a copper composite will be further described in detail with respect to FIGS. 5-10.

Next, the process provides (at stage 4) one or more features/components (e.g., composite conductive traces 411) for the core layer 402. In some implementations, the features may be defined from the metal layers 404-406. Different implementations may define the features differently. In some implementations, the process provides the features (e.g., composite conductive traces 411) by using a dry film patterning process, a dry film stripping process, and an etching process. Several dry film patterning, dry film stripping, and etching processes will further be described below with respect to FIGS. 5-10. Stage 4 conceptually represents the end result of using of these dry film patterning, dry film stripping and etching processes in some implementations. Examples of these processes include a modified semi additive process (mSAP) and a subtractive etching process.

The process then provides (at stage 5) a first prepreg layer 410 and a second prepreg layer 412. The prepreg layers 410 and 412 are a dielectric in some implementations. Often a substrate manufacturer or substrate supplier, may supply the prepreg layers 410 and 412 with a third metal layer 414 and a fourth metal layer 416. Different implementations may use different metal layers 414-416. In some implementations, one or both of the metal layers 414-416 is a copper material (e.g., copper composite foil). In some implementations, one or more of the metal layers (e.g., copper composite foil) may have a thickness of 2-5 microns (μm). In some implementations, one or more metal layers 414-416 may be a low CTE copper composite foil that has a thickness of 3-12 microns (μm). In such instances, the process may optionally etch down the thickness of the low CTE copper composite foil. In some implementations, one or more of the metal layers 414-416 may be a copper layer with a primer.

Next, the process performs (at stage 6) a drilling operation on the second prepreg layer 412, which defines one or more pattern features (e.g., via pattern feature 417) on the prepreg layer 412. The drilling operation may be a laser drilling operation. The process then performs (at stage 7) one or more plating processes, which defines the features (e.g., via feature 418) of the substrate. Different implementations may perform the plating process differently. In some implementations, an electroless copper composite seed is deposited on (e.g., the surface of) the pattern features (e.g., via pattern feature 417), which forms the via feature 418. Stage 7 illustrates that in some implementations, only the surface of the pattern feature 417 is covered, which means a layer of the electroless copper composite seed is formed on the wall of the feature 417. Some implementations may perform fill plating to define the features/components of the substrate. In some implementations, the fill plating and/or the electroless copper seed may be formed on one or more of the metal layers 414-416. That is, at stage 7, some implementations, may add an additional layer (e.g., copper, copper composite) on the metal layers 414-416. In some implementations, the layers 410 and 412 may be received without any metal layers 414-416 from substrate suppliers. Such layers 410 and 412 may be referred to as a buildup layer (e.g., layer when there is no copper foil). In such instances, at stage 7, the method may add/deposit/plate one or more metal layers (e.g., copper seed layer) on the prepreg layers 410 and 412. The various processes/methods for adding, depositing, or plating copper and/or a copper composite will be further described in detail with respect to FIGS. 5-10.

Next, the process provides (at stage 8) one or more features/components (e.g., composite conductive trace 420) for the prepreg layer 412. In some implementations, the features may be defined from the metal layer 416. Different implementations may define the features differently. In some implementations, the process provides/defines the features (e.g., composite conductive trace 420) by using a dry film patterning process, a dry film stripping process, and an etching process. Several dry film patterning, dry film stripping, and etching processes will further be described below with respect to FIGS. 5-10. Stage 8 conceptually represents the end result of using of these dry film patterning, dry film stripping and etching processes in some implementations. Examples of these processes include a modified semi additive process (mSAP) and a subtractive etching process.

While the example illustrated in FIGS. 4A-4D are for an mSAP process, a SAP process would follow a similar process except that the copper foil would be completely removed at the beginning of the process in some implementations.

In some implementations, additional layers may be added to the substrate. As such, the plating process may be repeated several times (e.g., stages 5-8 may be repeated) until a desired number of layers is reached.

Having described a shortened sequence for a paste process and a plating process, a more detailed description of the above processes will now be described below.

### Exemplary Flow Diagram for Plating and Paste Processes

FIG. 5 illustrates a flow diagram for a modified semi-additive processing (mSAP) patterning process for manufacturing a substrate that has a low coefficient of thermal expansion (CTE) copper composite material. FIG. 5 will be described with reference to FIG. 6 which illustrates a sequence of a layer (e.g., core layer, prepreg layer) of a substrate during the mSAP process of some implementations.

As shown in FIG. 5, the process 500 may start by thinning (at 505) a metal layer (e.g., copper composite material) on a dielectric layer. The dielectric layer may be a core layer or a prepreg layer of the substrate. In some implementations, the metal layer is thinned to a thickness of 3-5 microns (μm). The thinning of the metal layer is illustrated in stage 1 of FIG. 6, which illustrates a dielectric layer 602 that includes a thin copper layer 604 (which may be a copper composite material). In some implementations, the metal layer may already be thin enough. For example, in some implementations, the core layer or dielectric layer may be provided with a thin copper foil. As such, some implementations may bypass/skip thinning the metal layer of the core layer/dielectric layer. In addition, in some implementations electroless copper seed layer plating may performed to cover the surface of any drilled vias in one or more dielectric layers.

Next, the process applies (at 510) a dry film resist (DFR) and a pattern is created (at 510) on the DFR. Stage 2 of FIG. 6 illustrates a DFR 606 being applied on top of the thinned metal layer 604, while stage 3 of FIG. 6 illustrates the patterning of the DFR 606. As shown in stage 3, the patterning creates openings 608 in the DFR 606.

After patterning (at 515) the DFR, the process then electrolytically plates (at 520) a copper composite material through the pattern of the DFR. In some implementations, electrolytically plating comprises dipping the dielectric and the metal layer in a bath solution. Referring to FIG. 6, stage 4 illustrates copper composite materials 610 being plated in the openings 608 of the DFR 606.

Referring back to FIG. 5, the process removes (at 525) the DFR, selectively etches (at 530) the copper composite foil material to isolate the features (e.g., create components such vias, composite conductive traces, and/or pads) and ends. Referring to FIG. 6, stage 5 illustrates the removal of the DFR 606, while stage 6 illustrates the defined features after the etching process. The above process of FIG. 5 may be repeated for each core layer or prepreg layer (dielectric layer) of the substrate. Having described one plating process, another plating process will now be described.

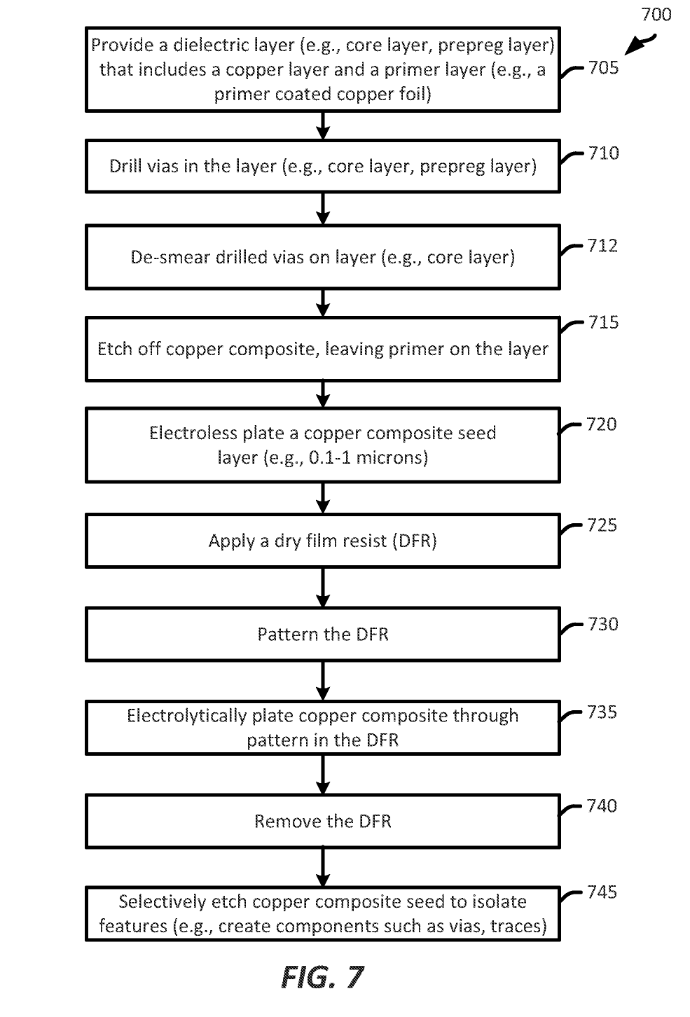

FIG. 7 illustrates a flow diagram for a semi-additive processing (SAP) patterning process for manufacturing a substrate that has a low CTE copper composite material. FIG. 7 will be described with reference to FIG. 8 which illustrates a sequence of a layer (e.g., core layer, prepreg layer) of a substrate during the SAP process of some implementations.

As shown in FIG. 7, the process 700 may start by providing (at 705) a dielectric layer that includes copper layer and a primer layer (e.g., a primer coated copper foil). In some implementations, the copper foil is coated with primer and then pressed on the uncured core to form the structure. The primer coated copper foil may be a copper foil. The dielectric layer may be a core layer or a prepreg layer of a substrate. As shown in stage 1 of FIG. 8, the primer 804 is located between the copper foil 806 and the dielectric 802. The copper foil 806 may be a copper composite foil in some implementations.

Next, the process drills (at 710) the dielectric layer (e.g., core layer, prepreg layer) to create one or more openings/pattern features (e.g., via pattern features). This may be done to form one or more vias/via features that connect the front and back side of the dielectric. In some implementations, the drilling may be performed by a laser drilling operation. Moreover, in some implementations, the drilling may traverse one or more the metal layers (e.g., primer coated copper foil). In some implementations, the process may also clean the openings/pattern features (e.g., via patterns) created by the drilling operation, by, for example, de-smearing (at 712) drilled vias/opening on the layer (e.g., core layer).

The process then etches off (at 715) the copper foil, leaving the primer on the dielectric layer (which is shown in stage 2 of FIG. 8). Next, the process electroless plates (at 720) a copper seed layer (e.g., copper material) on the primer in some implementations. The thickness of the copper seed layer in some implementations is about 0.1-1 microns (μm). Stage 3 of FIG. 8 illustrates a copper seed layer 808 on the primer 804.

Next, the process applies (at 725) a dry film resist (DFR) and a pattern is created (at 730) on the DFR. Stage 4 of FIG. 8 illustrates a DFR 810 being applied on top of the copper seed layer 808, while stage 5 of FIG. 8 illustrates the patterning of the DFR 810. As shown in stage 5, the patterning creates openings 812 in the DFR 810.

After patterning (at 730) the DFR, the process then electrolytically plates (at 735) a copper material (e.g., copper composite material) through the pattern of the DFR. In some implementations, electrolytically plating comprises dipping the dielectric and the metal layer in a bath solution. Referring to FIG. 8, stage 6 illustrates copper composite materials 814 being plated in the openings 812 of the DFR 810.

Referring back to FIG. 7, the process removes (at 740) the DFR, selectively etches (at 745) the copper seed layer to isolate the features (e.g., create vias, traces, pads) and ends. Referring to FIG. 8, Stage 7 illustrates the removal of the DFR 810, while Stage 8 illustrates the defined features (e.g., composite conductive trace) after the etching process.

The above process of FIG. 7 may be repeated for each core layer or prepreg layer (dielectric layer) of the substrate.

In some implementations, the SAP process may allow for finer/smaller feature (e.g., trace, vias, pads) formation since the SAP process does not require as much etching to isolate features.

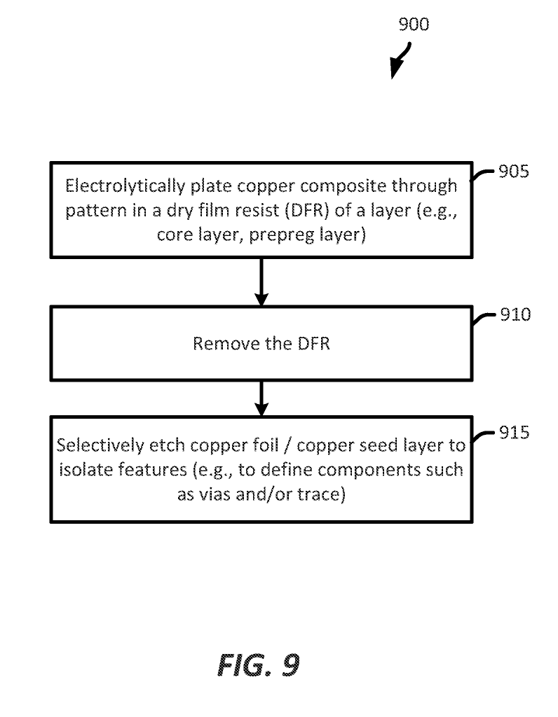

The plating processes of FIGS. 5 and 7 may be conceptually simplified to the plating process of FIG. 9 in some implementations. FIG. 9 illustrates a flow diagram for a plating method for manufacturing a substrate that has a low CTE copper composite material. As shown in FIG. 9, the method electrolytically plates (at 905) a copper composite through a pattern in a dry film resist (DFR) on a layer of a substrate. The layer may be a dielectric layer. The layer may be a core layer or a prepreg layer of the substrate. In some implementations, the copper composite is plated over a copper seed layer, which was previously deposited on the layer (e.g., when using a SAP process). In some implementations, the copper composite is plated over a copper foil layer, which was previously on the layer (e.g., when using an mSAP process). The copper foil layer may be a copper composite material in some implementations.

Next, the method removes (at 910) the DFR from the layer. In some implementations, removing the DFR may include chemically removing the DFR. After removing (at 910) the DFR, the method selectively etches (at 915) the foil or seed layer to isolate/define the features of the layer and ends. As described above, the foil may be a copper composite material.

In some implementations, a nickel alloy may be added (e.g., plated) over some or all of a copper layer (e.g., copper foil) during an mSAP process (e.g., methods of FIGS. 5, 6, and 9). Similarly, a nickel alloy may also be added (e.g., plated) over some or all of a copper layer (e.g., copper foil) during a subtractive process.

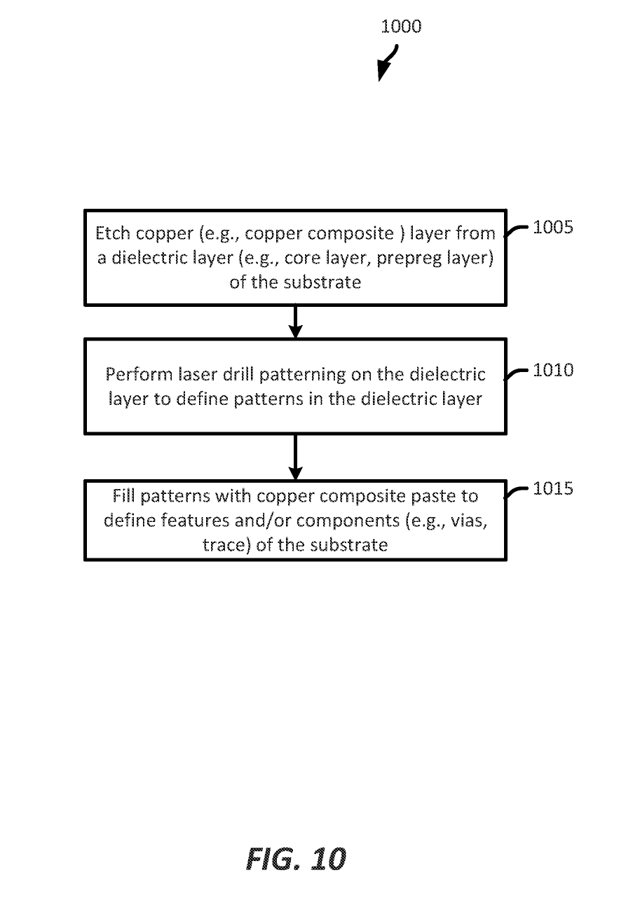

Similarly, the paste process described in FIGS. 3A-3D may be conceptually simplified to the paste method of FIG. 10 in some implementations. FIG. 10 illustrates a flow diagram for a paste method for manufacturing a substrate that has a low CTE copper composite material.

As shown in FIG. 10, the method etches (at 1005) a copper layer from a dielectric layer of the substrate. The dielectric layer may be a core layer or a prepreg layer of the substrate. The copper layer may be a metal layer that is located above and/or below the dielectric layer of the substrate in some implementations. Some or all of the copper layer may be removed during the selective etching.

Next, the method performs (at 1010) a laser drill patterning on the dielectric layer to define patterns in the dielectric layer. In some implementations, the patterns define the outlines of the features and/or components (e.g., vias, conductive trace) that are going to be manufactured/created in the substrate. In some implementations, laser drilling may include using a rastering technique to form the feature formation (e.g., trace, pad) at a specified depth in the dielectric followed by a full laser ablation process to form interconnect vias. In some implementations of the rastering process, a UV-YAG type laser may be used. In some implementations, a CO₂ laser may be used to form interconnect vias.

The method fills (at 1015) the patterns with copper composite paste to define the features and/or components of the substrates and ends. As mentioned above, examples of features and/or components include vias and traces.

### Exemplary Electronic Devices

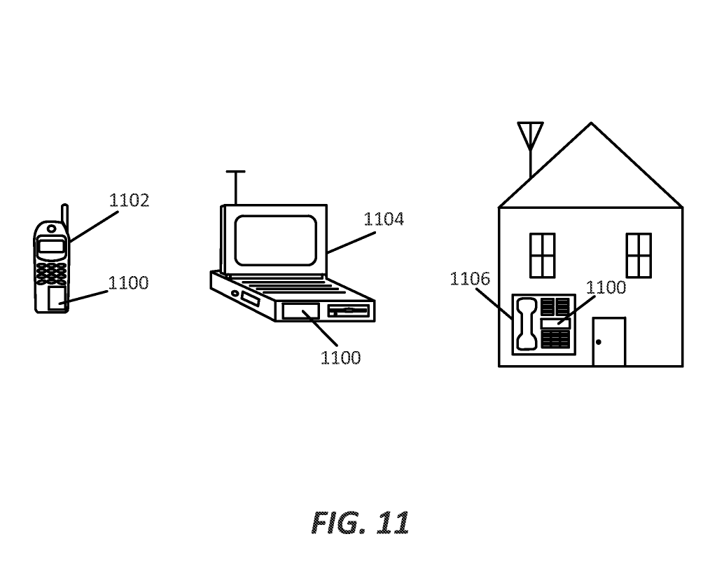

FIG. 11 illustrates various electronic devices that may be integrated with any of the aforementioned integrated circuit, die, chip or package. For example, a mobile telephone 1102, a laptop computer 1104, and a fixed location terminal 1106 may include an integrated circuit (IC) 1100. The IC 1100 may be, for example, any of the integrated circuits, dice or packages described herein. The devices 1102, 1104, 1106 illustrated in FIG. 11 are merely exemplary. Other electronic devices may also feature the IC 1100 including, but not limited to, hand-held personal communication systems (PCS) units, portable data units such as personal data assistants, GPS enabled devices, navigation devices, set top boxes, music players, video players, entertainment units, fixed location data units such as meter reading equipment, or any other device that stores or retrieves data or computer instructions, or any combination thereof.

One or more of the components, steps, features, and/or functions illustrated in FIGS. 1, 2, 3A-3D, 4A-4D, 5, 6, 7, 8, 9, 10 and/or 11 may be rearranged and/or combined into a single component, step, feature or function or embodied in several components, steps, or functions. Additional elements, components, steps, and/or functions may also be added without departing from the invention.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other.

It is noted that term “core layer” may mean to include metals layers (e.g., copper layer, copper composite layer, copper foil, copper composite foil) that are coupled to the core layer. Similarly, the term “prepreg layer” and/or “dielectric layer” may also mean to include metals layers (e.g., copper layer, copper composite layer, copper foil, copper composite foil) that are coupled to the prepreg layer and/or dielectric layer. The substrate described above that includes the core layer and the dielectric layers (e.g., prepreg layers) may be a substrate for an integrated circuit and/or a printed circuit board (PCB) in some implementations.

Also, it is noted that the embodiments may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

The various features of the invention described herein can be implemented in different systems without departing from the invention. It should be noted that the foregoing aspects of the disclosure are merely examples and are not to be construed as limiting the invention. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A substrate comprising:
a first dielectric layer;
a second dielectric layer, the first and second dielectric layers having a first coefficient of thermal expansion (CTE);
a core layer between the first dielectric layer and the second dielectric layer; and
a composite conductive trace between the first dielectric layer and the second dielectric layer, the composite conductive trace includes copper and another material, the composite conductive trace having a second CTE that is less than a third CTE for copper to more closely match the first CTE for the first and second dielectric layers.

2. The substrate of claim 1, wherein the second CTE is less than 17 parts-per-million per degree Celsius.

3. The substrate of claim 1, wherein the another material is carbon nanotubes (CNTs).

4. The substrate of claim 4, wherein the CNTs include nanotubes coated with a mixed shell of zwitterrionic and a positively charged conductive polymer.

5. The substrate of claim 4, wherein the CNTs include nanotubes coated with a mixed shell of zwitterrionic and a non conductive polymer

6. The substrate of claim 1, wherein the another material has a fourth CTE value that is negative.

7. The substrate of claim 6, wherein the another material is a nickel/tin alloy.

8. The substrate of claim 1, wherein the substrate is for an integrated circuit (IC).

9. The substrate of claim 1, wherein the substrate is for a printed circuit board (PCB).

10. The substrate of claim 1, wherein the composite conductive trace is located between the core layer and the first dielectric layer.

11. A method for manufacturing a substrate, comprising:
providing a core layer for the substrate;
providing a composite conductive trace, the composite conductive trace includes copper and another material, the composite conductive trace having a first coefficient of thermal expansion (CTE) that is less than a second CTE for copper to more closely match a third CTE for a first and second dielectric layers; and
providing the first and second dielectric layers, such that the core layer is between the first and second dielectric layers.

12. The method of claim 11, wherein providing the composite conductive trace includes thinning a copper composite layer on at least one of the core layer, first dielectric layer and/or second dielectric layer.

13. The method of claim 12, wherein the copper composite layer is a copper composite foil.

14. The method of claim 11, wherein providing the composite conductive trace includes electrolytically plating a copper composite layer on at least the core layer.

15. The method of claim 11, wherein providing the composite conductive trace includes electrolytically plating a copper composite layer on at least the first dielectric layer.

16. The method of claim 11, wherein providing the composite conductive trace includes electroless plating a copper layer on at the least the core layer.

17. The method of claim 11, wherein providing the composite conductive trace includes electroless plating a copper layer on at the least the first dielectric layer.

18. The method of claim 11, wherein providing the composite conductive trace includes:
drilling the core layer to provide a trace pattern on the core layer; and
filling the trace pattern with a copper composite paste to provide the composite conductive trace.

19. The method of claim 18, wherein providing the composite conductive trace further includes etching a copper composite layer on the core layer before drilling the core layer.

20. The method of claim 11, wherein providing the composite conductive trace includes filling a trace pattern with a copper composite paste, the trace pattern in at least one of the core layer, first dielectric layer and/or second dielectric layer.

21. The method of claim 11, wherein providing the composite conductive trace comprises:
applying a dry film resist (DFR) on a first copper layer of the core layer;
patterning the DFR;
electrolytically plate a second copper composite layer through the DFR;
removing the DFR; and
selectively etching the first copper layer of the particular dielectric layer to provide the composite conductive trace.

22. The method of claim 21, wherein providing the composite conductive trace further comprises drilling at least one via pattern in the core layer before applying the DFR on the first copper layer of the core layer.

23. The method of claim 21, wherein the first copper layer is a copper foil having at thickness of 5 microns (μm) or less.

24. The method of claim 21, wherein providing the composite conductive trace further includes thinning the first copper layer before applying the DFR on the first copper layer of the core layer, the first copper layer being a copper composite foil having a thickness of 12 microns (μm) or less before the thinning.

25. The method of claim 11, wherein providing the composite conductive trace comprises:
providing a first copper layer and a primer layer on the core layer, the primer layer located between the first copper layer and the core layer;
etching the first copper layer, the etching leaving at least some of the primer layer on the core layer;
electroless plating a second copper layer on top of the layer of primer;
applying a dry film resist (DFR) on top of the second copper composite layer;
patterning the DFR;
electrolytically plate a third copper composite layer through the DFR;
removing the DFR; and
selectively etching the second copper composite layer of the core layer to provide the composite conductive trace.

26. The method of claim 11, wherein the another material is carbon nanotubes (CNTs).

27. The method of claim 26, wherein the CNTs include nanotubes coated with a mixed shell of zwitterrionic and a positively charged conductive polymer.

28. The method of claim 11, wherein the another material is a nickel/tin alloy.

29. The method of claim 11, wherein the substrate is for an integrated circuit (IC).

30. The method of claim 11, wherein the substrate is for a printed circuit board (PCB).

31. The method of claim 11, wherein the composite conductive trace is located between the core layer and the first dielectric layer.
